(19) United States
(12) Patent Application Publication
(10) Pub. No.: US 2006/0118242 A1
(43) Pub. Date: Jun. 8, 2006

(54) Atmospheric pressure plasma system

(76) Inventors: Anthony Herbert, Cork (IE); Fergal O'Reilly, Rinesend (IE); Jules Braddell, Cork (IE); Peter Dobbyn, Cork (IE)

Correspondence Address: MCKELLAR IP LAW, PLLC, 784 SOUTH POSEYVILLE ROAD, MIDLAND, MI, 48640, US

(21) Appl. No.: 11/333,939

(22) Filed: Jan. 18, 2006

Related U.S. Application Data
(63) Continuation of application No. 10/204,894, filed on Dec. 2, 2002, now abandoned.

(51) Int. Cl. C23F 1/00; C23C 16/00

(52) U.S. Cl. 156/345.43; 118/718; 156/345.31

(57) ABSTRACT

An atmospheric pressure plasma system (1) sharing electrodes (4) defining a plasma region (5) mounted in an enclosure housing (2). The enclosure housing has an open to atmosphere entry port assembly (10) and exit port assembly (11) for the continuous transfer of work-pieces through the plasma region (5). The embodiment illustrated is for precursor process gases having a relative density less than that of the ambient air so that the precursor gases rise in the enclosure housing (2) expelling the heavier ambient and exhaust gases. Where the gases have a relative density greater than ambient the port assemblies (10 and 11) are sited above the plasma region (5).

This a Continuation of U.S. Utility application Ser. No. 10/204,894, filed Dec. 2, 2002.

The present invention relates to an atmospheric pressure plasma system and in particular to a method and process for using plasmas at atmospheric and/or ambient pressure in industrial manufacturing, processing and production using precursor process gases other than ambient air.

When matter is continually supplied with energy, its temperature increases and it typically transforms from a solid to a liquid and, then, to a gaseous state. Continuing to supply energy causes the system to undergo yet a further change of state in which neutral atoms or molecules of the gas are broken up by energetic collisions to produce negatively charged electrons, positive or negatively charged ions and other species. This mix of charged particles exhibiting collective behaviour is called “plasma”, the fourth state of matter. Due to their electrical charge, plasmas are highly influenced by external electromagnetic fields which makes them readily controllable. Furthermore, their high energy content allows them to achieve processes which are impossible or difficult through the other states of matter, such as by liquid or gas processing.

The term “plasma” covers a huge range of systems whose density and temperature vary by many orders of magnitude. Some plasmas are very hot and all their microscopic species (ions, electrons, etc.) are in approximate thermal equilibrium, the energy input into the system being widely distributed through atomic/molecular level collisions. Other plasmas, however, particularly those at low pressure (e.g. 100 Pa) where collisions are relatively infrequent, have their constituent species at widely different temperatures and: are called “non-thermal equilibrium” plasmas. In these non-thermal plasmas the free electrons are very hot with temperatures of many thousands K while the neutral and ionic species remain cool. Because the free electrons have almost negligible mass, the total system heat content is low and the plasma operates close to room temperature thus allowing the processing of temperature sensitive materials, such as plastics or polymers, without imposing a damaging thermal burden onto the sample. However, the hot electrons create, through high energy collisions, a rich source of radicals and excited species with a high chemical potential energy capable of profound chemical and physical reactivity. It is this combination of low temperature operation plus high reactivity which makes non-thermal plasmas technologically important and a very powerful tool for manufacturing and material processing, capable of achieving processes which, if achievable at all without plasma, would require very high temperatures or noxious and aggressive chemicals.

For industrial applications of plasma technology, a convenient method is to couple electromagnetic power into an enclosure backfilled with process gas (which term “gas” shall hereinafter include gas mixtures and vapours) and containing the work-pieces/samples to be treated. The gas becomes ionised into plasma generating the chemical radicals, UV-radiation and ions which react with the surface of the samples. By correct selection of process gas composition, driving power frequency, power coupling mode, pressure and other control parameters, the plasma process can be tailored to the specific application required by the manufacturer.

Because of the huge chemical and thermal range of plasmas, they are suitable for many technological applications which are being continually extended. Non-thermal equilibrium plasmas are particularly effective for surface activation, surface cleaning/material etching and coating of surfaces.

The surface activation of polymeric materials is a widely used industrial plasma technology pioneered by the automotive industry. Thus, for example, the polyolefines, such as polyethylene and polypropylene, which are favoured for their recylability, have a non-polar surface and consequent poor disposition to coating or gluing. However, treatment by oxygen plasma results in the formation of surface polar groups giving high wettability and consequent excellent coverage and adhesion of metal paint, adhesive or other coating. Thus, for example, plasma surface engineering is essential to the manufacture of vehicle fascias, dashboards, bumpers etc. and to component assembly in the toy, etc. industries. Many other applications are available in the printing, painting, gluing, laminating and general coating of components of all geometries in polymer, plastic, ceramic/inorganic, metal and other materials.

The increasing pervasiveness and strength of environmental legislation world-wide is creating substantial pressure on industry to reduce or eliminate the use of solvents and other wet chemicals in manufacturing, particularly for component/surface cleaning. In particular, CFC-based degreasing operations have been largely replaced by plasma cleaning technology operating with oxygen, air or other non-toxic gases. Combining water based pre-cleaning with plasma, even heavily soiled components can be cleaned and surface qualities obtained typically superior to those resulting from traditional methods. Any organic surface contamination is rapidly scavenged by room temperature plasma and converted to gaseous CO₂ and water which can be safely exhausted.

Plasmas can also carry out etching of a bulk material, i.e. removal of unwanted material. Thus, for example, an oxygen based plasma will etch polymers, a process used in the production of circuit boards, etc. Different materials such as metals, ceramics and inorganics are etched by careful selection of precursor gas and attention to the plasmachemistry. Structures down to nanometre critical dimension are now being produced by plasma etching technology.

A plasma technology that is rapidly emerging into mainstream industry is that of plasma coating/thin film deposition. Typically, a high level of polymerisation is achieved by application of plasma to monomeric gases and vapours. Thus, a dense, tightly knit and three-dimensionally connected film can be formed which is thermally stable, chemically very resistant and mechanically robust. Such films are deposited conformally on even the most intricate of surfaces and at a temperature which ensures a low thermal burden on the substrate. Plasmas are therefore ideal for the coating of delicate and heat sensitive, as well as robust materials. Plasma coatings are free of micropores even with thin layers (e.g. 0.1 mm). The optical properties, e.g. colour, of the coating can often be customised and plasma coatings adhere well to even non-polar materials, e.g. polyethylene, as well as steel (e.g. anti-corrosion films on metal reflectors), ceramics, semiconductors, textiles, etc.

In all these processes, plasma engineering produces a surface effect customised to the desired application or product without affecting the material bulk in any way. Plasma processing thus offers the manufacturer a versatile and powerful tool allowing choice of a material for its bulk technical and commercial properties while giving the freedom to independently engineer its surface to meet a totally different set of needs. Plasma technology thus confers greatly enhanced product functionality, performance, lifetime and quality and gives the manufacturing company significant added value to its production capability.

These properties provide a strong motivation for industry to adopt plasma-based processing, and this move has been led since the 1960s by the microelectronics community which has developed the low pressure Glow Discharge plasma into an ultrahigh technology and high cost engineering tool for semiconductor, metal and dielectric processing. The same low pressure Glow Discharge type plasma has increasingly penetrated other industrial sectors since the 1980s offering, at more moderate cost, processes such as polymer surface activation for increased adhesion/bond strength, high quality degreasing/cleaning and the deposition of high performance coatings. Thus, there has been a substantial take-up of plasma technology.

However, adoption of plasma technology has been limited by a major constraint on most industrial plasma systems, namely their need to operate at low pressure. Partial vacuum operation means a closed perimeter, sealed reactor system providing only off-line, batch processing of discrete work-pieces. Throughput is low/moderate and the need for vacuum adds capital and running costs.

Atmospheric pressure plasmas, however, offer industry open port/perimeter systems providing free ingress into and exit from the plasma region by work-pieces/webs and, hence, on-line, continuous processing of large or small area webs or conveyor-carried discrete work-pieces. Throughput is high, reinforced by the high species flux obtained from high pressure operation. Many industrial sectors, such as textiles, packaging, paper, medical, automotive, aerospace, etc., rely almost entirely upon continuous, on-line processing so that open port/perimeter configuration plasmas at atmospheric pressure offer a new industrial processing capability.

Corona and flame (also a plasma) treatment systems have provided industry with a limited form of atmospheric pressure plasma processing capability for about 30 years. However, despite their high manufacturability, these systems have failed to penetrate the market or be taken up by industry to anything like the same extent as the low pressure, batch-processing-only plasma type. The reason is that corona/flame systems have significant limitations. They operate in ambient air offering a single surface activation process and have a negligible effect on many materials and a weak effect on most. The treatment is often non-uniform and the corona process is incompatible with thick webs or 3D work-pieces while the flame process is incompatible with heat sensitive substrates. It has become clear that atmospheric pressure plasma technology must move much deeper into the atmospheric pressure plasma spectrum to develop advanced systems meeting industry needs. However, to do this, it is essential to move from ambient air plasmas to plasmas formed from other precursor process gases. Such plasmas have properties different to ambient air plasmas and, thus, the potential for new and/or improved industrial processes. However, any move to new types of atmospheric pressure plasmas will only be industrially relevant if they include the ability to operate in the open port/perimeter configuration consistent with on-line, continuous manufacture.

A wide range of potentially useful industrial processes based upon non-ambient-air plasmas at atmospheric pressure have been demonstrated by researchers including surface activation, etching/cleaning and surface coating. Such processes rely upon the use of non-ambient-air precursor gases including Helium, Argon, Nitrogen, Oxygen, Halocarbons, Silanes, organic and inorganic monomers, Halogens, SiCl₄, SiF₄, Hydrocarbons, Hydrogen, etc. Such gases are costly and/or hazardous and/or environmentally harmful and require containment in and confinement to the region in which the plasma is generated and the work-piece processed and close thereto. Furthermore, the composition of the process gas in the plasma region must be tightly controlled for process optimisation and reproducibility, so that the introduction of contaminant gases from the ambient air surrounding the plasma system must be eliminated or minimised. These requirements motivate a precursor process gas containment system as an integral part of any novel industrial atmospheric pressure plasma processing system using non-ambient-air process gas which confines injected process gas to and near to the plasma region and minimises or prevents the incursion into the plasma region of unwanted ambient air or other gas while, at the same time, allows the open port/perimeter configuration essential to on-line, continuous production.

The present invention is directed towards providing these and other objects.

### STATEMENTS OF INVENTION

According to the invention, there is provided an atmospheric pressure plasma (APP) system of the non-thermal equilibrium type comprising: electrodes forming a plasma region mounted in an enclosure housing a non-ambient air precursor process gas having a relative density greater or less than ambient air at the same pressure and temperature, characterised in that the system comprises: a gas-fight enclosure housing having an open to the atmosphere entry port assembly and exit port assembly, each assembly port having a work-piece port opening and a work-piece enclosure opening, wherein the port assemblies are above the plasma region for precursor process gas with a relative density greater than that of the ambient air and below for a gas with a relative density less than that of ambient air; and means for moving work-pieces between the electrodes from the entrance port assembly to the exit port assembly. The advantage of this construction is that most of the precursor process gas does not escape out the plasma region during continuous operation. That obviates the high cost of large quantities of expensive precursor process gas and further, by reducing the extent of the loss of gas, health and safety hazards are greatly reduced since many of the precursor process gas may be toxic, an asphyxiant, an irritant and even harmful explosive. A further advantage is that by keeping the plasma region relatively free of contaminants, a more efficient control of the process may be carried out with increased replicability.

According to the invention, each port assembly comprises an elongate enclosed housing with the work-piece port opening and the work-piece enclosure opening spaced vertically apart. The longer the housing is, the less likelihood there is of contaminant gases entering the housing. Ideally, a gas analyser is mounted in the entry port assembly and preferably it is located adjacent the work-piece enclosure opening. Further, a gas analyser may be mounted in the exit part assembly and ideally is mounted adjacent the work-piece port opening. In both cases, the gas analyser may be connected to a control means for the introduction of precursor process gas on the quantity of precursor process gas sensed by the analyser falling below a predetermined level.

Ideally, the precursor process gas is maintained at a slight positive pressure above ambient pressure outside the enclosure housing. In this way, by a relatively modest increase in pressure within the enclosure housing, it is possible to keep the enclosure free of contaminant gases.

Ideally, the positive pressure of the precursor process gas is less than 1% of ambient.

In one embodiment of the invention, control means are provided whereby the positive pressure is maintained by the introduction of precursor process gas when the pressure within the enclosure housing falls below a predetermined minimum level. Alternatively, means are provided for continuously introducing precursor process gas into the enclosure housing. Ideally, means are provided for the collection and removal of gases adjacent the exterior of each port assembly where a work-piece enters or leaves the port assembly.

In one embodiment of the invention, the means for collection and removal of the gases comprise a cowling surrounding the port assemblies and an extraction fan associated therewith. In one embodiment of the invention, the cowling comprises an open gas receiving mouth adjacent the work-piece port opening. The advantage of this is that the gases, whether they be exhaust gases or precursor process gases are withdrawn from the enclosure housing, particularly where the enclosure housing is pressurised. They may be collected for recycling or at least for safe disposal.

In another embodiment, an exhaust gas vent is provided in the enclosure on the side of the enclosure opposite to the port assemblies for the collection of exhaust gases having a relative density to that of the process precursor gases whereby they are trapped in the enclosure housing. In this latter embodiment, an exhaust gas sensor is mounted in the enclosure housing adjacent the exhaust gas vent. Then control means may be connected to the exhaust gas sensor and the exhaust gas vent for the operation of the exhaust gas vent on the level of exhaust gases in the enclosure housing exceeding a predetermined level.

Ideally gas flow dampers are mounted in each port assembly. Such gas flow dampers may be one or other of lip seals; brush seals; curtain seals; and opposed rollers. Other well known gas dampers do not need any further description but anything that will reduce the perturbation of the gas is to be preferred.

In one embodiment of the invention, the electrodes are substantially planar electrodes. In the latter embodiment of the invention, there are a plurality of electrodes arranged back to back and in which the means for moving the work-pieces between the electrodes comprises a conveyor or a web moving back and forth sequentially between the electrodes.

In another embodiment of the invention, when the work-piece is endless yarn, the means provided for moving the work-piece comprises an open frame member for mounting between two electrodes, the frame member carrying a plurality of yarn support pulleys on opposite sides of the frame member and a yarn draw-off mechanism.

It is envisaged that the electrodes may comprise a pair of U-shaped members of dielectric material nesting one inside the other to define the plasma region therebetween carrying an electrode on the outer surface of the outer of the two members and carrying a corresponding electrode on the inner surface of the other member.

### DETAILED DESCRIPTION OF THE DRAWINGS

The invention will be more clearly understood from the following description of some embodiments thereof, given by way of example only, with reference to the accompanying drawings, in which:—

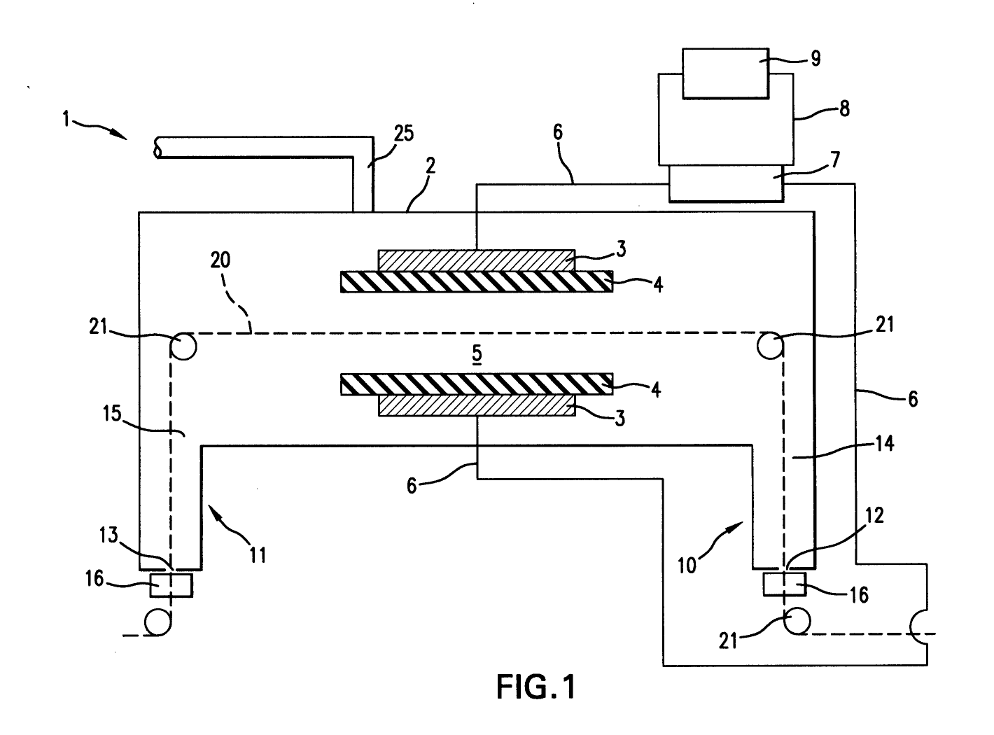

FIG. 1 is a diagrammatic view of an atmospheric pressure plasma system according to the invention,

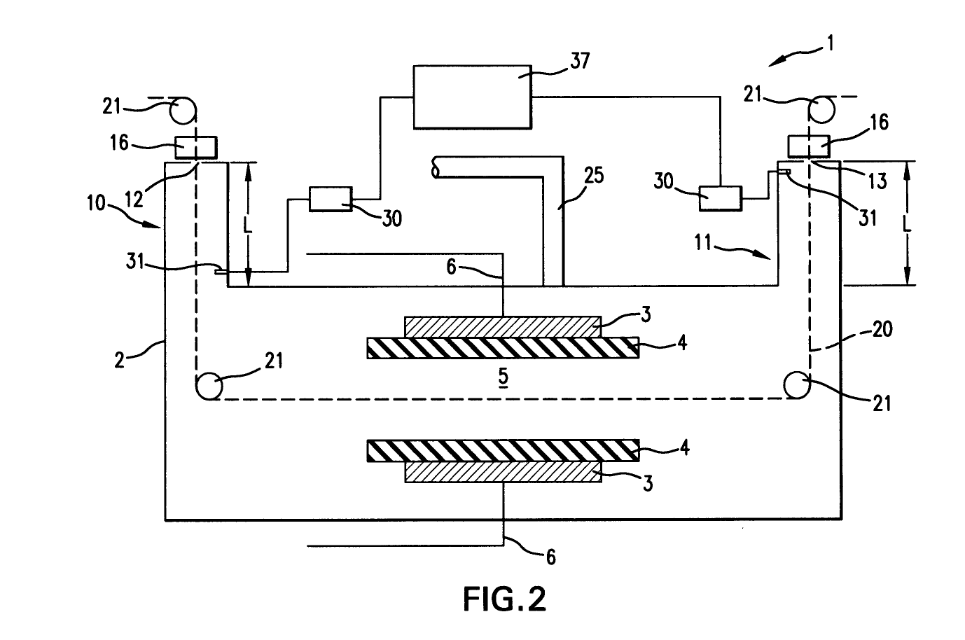

FIGS. 2 to 6 are diagrammatic views of other systems according to the invention,

FIG. 7 is an exploded schematic view of a system according to the invention,

FIG. 8 is a detailed view of a yarn handling rack according to the invention,

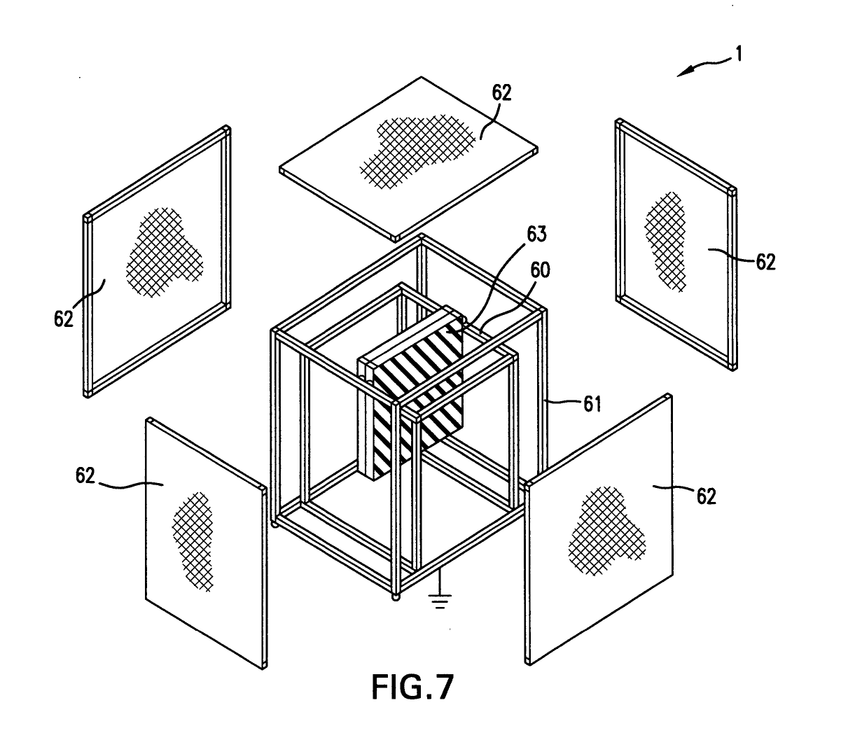

FIG. 9 is a perspective view of an electrode arrangement for use with the yarn handling rack of FIG. 8,

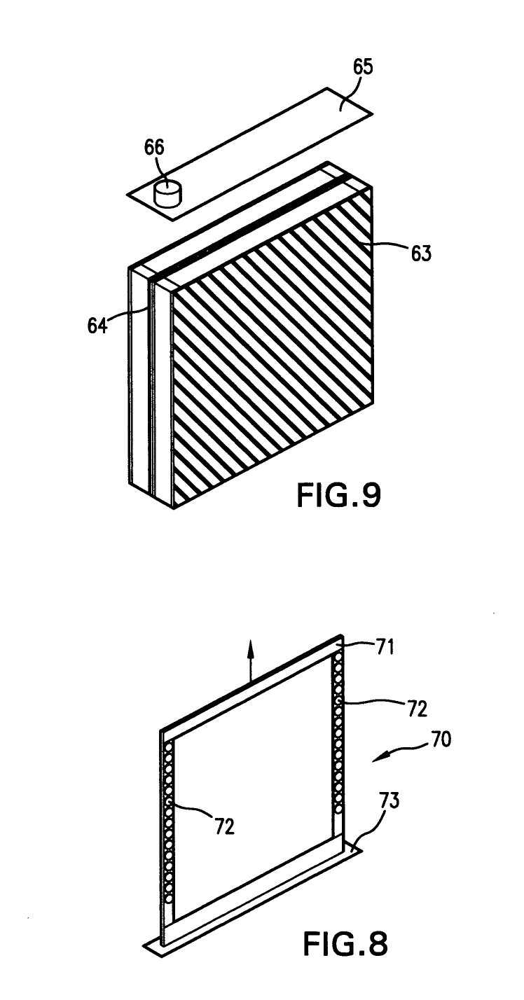

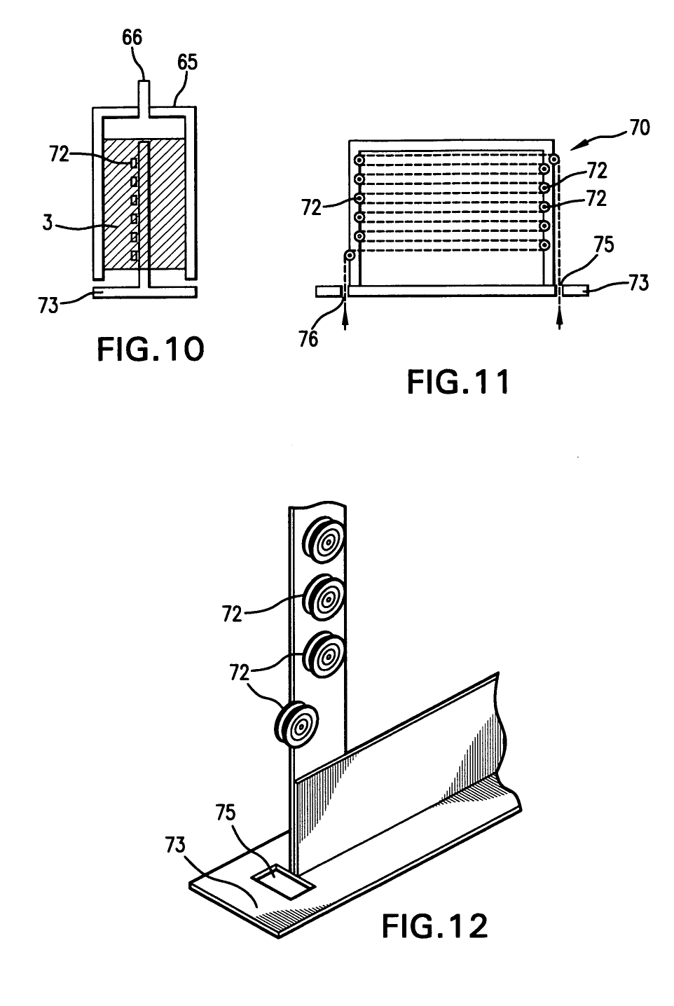

FIG. 10 is a side view of the yarn handling rack and electrode assembly of FIGS. 8 and 9 assembled together,

FIG. 11 is a front view of the yarn handling rack, and

FIG. 12 is an enlarged perspective view of part of the yarn handling rack.

Before referring to the drawings, it will be appreciated that a precursor process gas or vapour will have a unique density and thus a unique relative density. In this specification, relative density is the ratio of the density of a gas to the density of the ambient air at the same temperature and pressure. When discussing “precursor process gas”, one is referring to the ratio of the density of that gas to the density of ambient air at the same temperature and pressure. Therefore, if this ratio is less than 1, the gas is lighter than the ambient air and will tend to rise and float above the ambient air while, if the ratio or density is greater than 1, then the gas is heavier than the ambient air and will tend to sink.

Essentially, the principle of the present invention is that by encasing the plasma region in an enclosure housing which is gas tight, except for open port assemblies allowing free ingress to the plasma and exit therefrom by work-pieces then, if the open port assemblies are sited correctly, then it is possible to avoid the escape of the precursor process gas. In the case of the relative density of the precursor process gas being less than 1, then the entry port assembly and the exit port assembly must be sited in the lowest part of the enclosure housing. When this is done, then all the precursor process gas, when injected into the enclosure housing, will rise to fill the enclosure housing from the top down duly expelling all the ambient air out of the enclosure housing or at least away from the plasma region defined by the electrodes. Similarly, in the case of the precursor process gas having a relative density greater than 1, then the precursor process gases will naturally fall within the enclosure housing and thus the enclosure housing will have to have its entry and exit port assemblies in the highest part of the housing enclosure.

Needless to say, in this specification, highest and lowest is used in its normal sense, that is to say, the highest being furthest away from the gravitational pull of the earth, and the lowest being closer.

Referring to the drawings and initially to FIG. 1, there is illustrated an atmospheric pressure plasma (APP) system, indicated generally by the reference numeral 1 of the non-thermal equilibrium type comprising an enclosure housing 2 containing a pair of electrodes 3 mounted on a dielectric material 4 forming therebetween a plasma region 5. The dielectric can be any suitable dielectric such as glass. The electrodes 3 are connected in conventional manner by electric leads 6 to a suitable RF (radio frequency) transformer 7 connected by suitable cabling 8 to an RF supply 9. The enclosure housing 2 is gas tight except for an entry port assembly, indicated generally by the reference number 10, and an exit port assembly, indicated generally by the reference numeral 11. The entry port assembly 10 and the exit port assembly 11 each have a work-piece opening 12 and 13 and a work-piece enclosure opening 14 and 15 respectively. The two work-piece enclosure openings 14 and 15 are in this embodiment, directly above the work-piece port openings 12 and 13. Adjacent each work-piece opening 12 and 13, there is mounted suitable gas flow dampers 16. The gas flow dampers 16 can be in the form of lip seals, brush seals, opposing rollers or curtain seals, indeed, all types of seal. Means for moving work-pieces through the enclosure housing is provided by a conveyor or web 20 shown by interrupted lines travelling across pulleys 21. The conveyor 20 is not shown in any detail nor indeed, for example, is the drive or return pulleys of the conveyor 20. However, all of these are conventional. The conveyor 20 simply comprises means for holding work-pieces to deliver the work-pieces through the plasma region 5. Alternatively, if the work-piece is in the form of a web it is simply tensioned over the pulleys 21 and pulled through the plasma region 5. A suitable gas feed pipe 25 for injection of precursor process gas is illustrated and is connected to a source of precursor process gas which is not shown.

In operation, suitable precursor gas lighter than air such as, for example, helium, having a relative density less than that of the ambient air at the temperature and ambient pressure prevailing, i.e. less than 1.0 as defined above, is fed into the enclosure housing 2 through the gas feed pipe 25. The lighter than air gas will occupy initially the top of the enclosure housing 2 and then will gradually fill up the enclosure as more is fed in pushing out the ambient air until there is no ambient air in the enclosure housing 2 or in either the entry port assembly 10 or the exit port assembly 11. The work-pieces are placed on the conveyor 20 and the conveyor 20 is operated to bring work-pieces through the plasma region 5 and with the plasma system operating, then the necessary plasma processing will take place in the plasma region 5.

In operation, as the conveyor 20 progresses through the gas flow damper 16 into the work-piece opening 12, the gas flow damper 16 will minimise the entry of ambient air into the system and thus will ensure that there will be little or no perturbation of the plasma. Further, the gas flow dampers will ensure that little contaminating ambient air be dragged or carried into the enclosure housing 2. Generally, on exiting out the work-piece port opening 13, the gas flow dampers 16 will prevent the dragging out of precursor process gas into the surrounding atmosphere. The embodiment of FIG. 1 is a simple construction of the atmospheric process plasma system according to the invention.

FIG. 2 illustrates an alternative construction of APP system, again identified by the reference numeral 1 and parts similar to those described with reference to the previous drawing, are identified by the same reference numerals. In this embodiment, the APP system 1 is adapted for use with precursor process gases whose relative density is greater than 1, that is to say, their density is greater than that of the ambient air at the same pressure and temperature. In this embodiment, there is provided a pair of gas analysers 30 each having a probe 31, one is sited in the entry port assembly 10 adjacent the work-piece enclosure opening 14 and the other in the exit port assembly 11 adjacent the work-piece port opening 13. Both gas analysers 30 are connected to a controller 37 in turn connected to the precursor gas supply. When the gas analysers 30 indicate that either the entry port assembly 10 is becoming contaminated with ambient air adjacent the work-piece enclosure opening 14 or the entry port assembly 11 is removing too much of the precursor process gas through the work-piece port opening 13, the precursor gas flow can be adjusted accordingly. The greater the length L is, that is to say, the vertical distance between the work-piece port opening and the work-piece enclosure opening the less the amount of contaminants will enter. The port assemblies will form what are in effect gas traps.

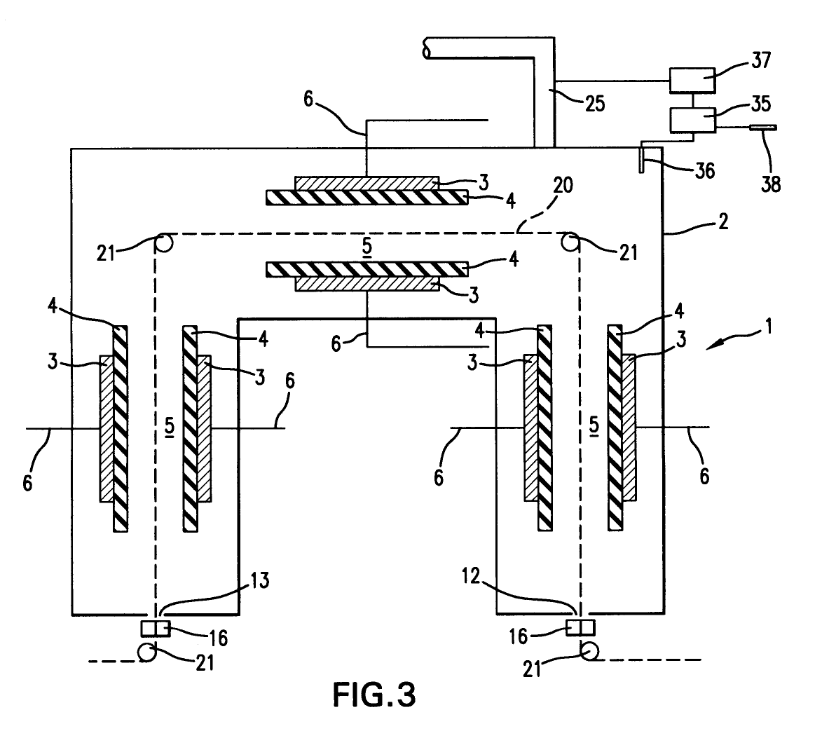

Referring to FIG. 3, there is illustrated a further APP system, again identified generally by the reference numeral 1 and parts similar to those described with reference to the previous drawings, are identified by the same reference numerals. In this embodiment, there is provided a gas pressure sensor 35 having probes 36 and 38. The gas pressure sensor 35 is connected to a controller 37 which is in turn connected to the precursor gas supply. The probe 36 is inside the enclosure housing 2 and the probe 38 is mounted outside the enclosure housing 2 to sense ambient pressure.

In operation, the gas pressure sensor 35 records both the pressure inside the enclosure housing 2 and the pressure outside the enclosure housing 2 and delivers both signals to the controller 37, which controller 37 then operates the precursor gas supply to maintain the pressure within the enclosure housing 2 at a preset amount above the ambient pressure. While maintaining the precursor process gas at an elevated pressure will ensure the loss of a certain amount of gas, this gas, however, can be collected at the entry port assembly 10 and the exit port assembly 11 as will be described later. Since the pressure difference is very small, it has been found that, in practice, less than 10 litres per minute from a large system is lost and, as mentioned above, the gas can be collected for recycling. In this particular embodiment, there is shown a mixture of both vertical and horizontal electrode arrays, that is to say, with plasma regions through which the work-piece travels in the horizontal direction or in the vertical direction. Such a configuration can produce in each plasma region 5, an atmospheric pressure plasma of the dielectric barrier or silent discharge type or the Corona discharge type, or the atmospheric pressure Glow Discharge type, or any other type of plasma system, depending upon various well known parameters such as gap distance, drive frequency and electrode geometry.

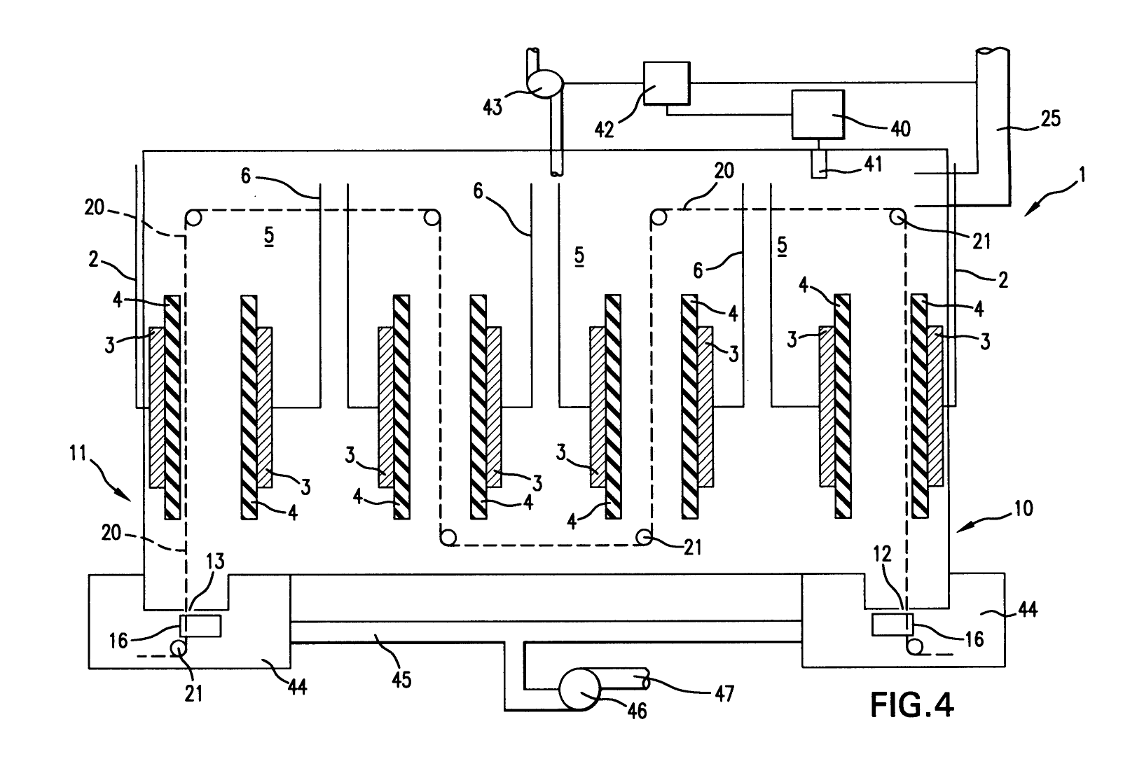

Referring now to FIG. 4, there is illustrated another construction of APP system, again indicated generally by the reference numeral 1. This embodiment illustrates a series of identical vertically arranged electrodes 3 defining effectively vertical plasma regions 5 and it will be noted that a conveyor 20 now moves up and down between the electrode 7 or, depending on how it is considered, back or forth between the electrodes. The one thing that should be noted from this embodiment is that the gas feed pipe 25 is now mounted lower down the enclosure housing 2. In this embodiment, there is mounted a gas analyser 40 having a probe 41 in the upper portion of the enclosure housing 2 remote from the two port assemblies 10 and 11. Connected to the gas analyser 40 is a controller 42 which is in turn connected to an extract fan 43.

A cowling 44 is mounted around each port assembly 10 and 11 and is connected by a conduit 45 to an extract fan 46 which is in turn connected to an extract pipe 47. Gases which are adjacent two port assemblies 10 and 11 will be removed through the cowling 44 by the extract fan 46 for, if necessary, recycling. This embodiment would be particularly useful when the APP system is operated at a pressure greater than atmospheric pressure. In many instances, the fan 46 is not required.

The gas analyser 40 is used to sense the presence of exhaust gases which, in this embodiment, rise to the top of the enclosure housing 2 and are thus lighter than the precursor process gas. These are then removed by the extract fan 46 either to be discharged into the atmosphere or for collection. It will be appreciated that the extract pipe 47 can be connected to a gas collector which, when there is a slight positive pressure in the enclosure 2, is likely to be almost pure precursor process gas. Exhaust gases heavier than the precursor process gas is delivered out the port assemblies 10 and 11.

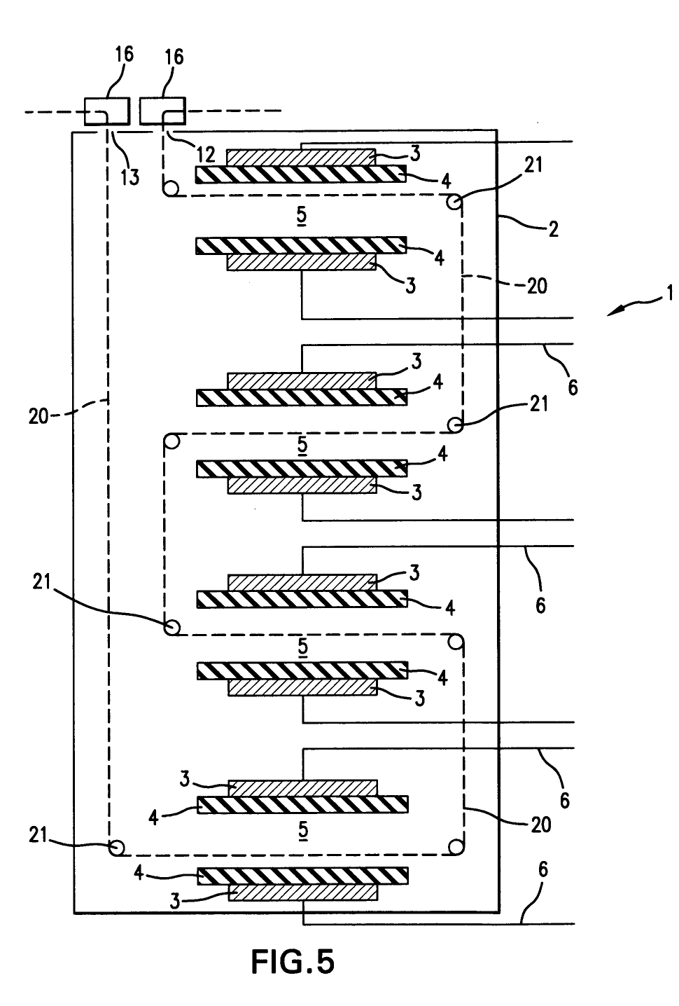

Referring now to FIG. 5, there is illustrated a still further construction of APP system, again indicated generally by the reference numeral 1 and parts similar to those described with reference to previous embodiments are identified by the same reference numerals. In this embodiment, it will be noted that the entry port assembly 10 and the exit port assembly are not formed from an enclosed elongate housing but that the work-piece opening and the work-piece enclosure opening are coincident. It will be noted that in this embodiment, the plasma regions 5 are effectively horizontal and the work-piece passes back and forth between electrodes. This embodiment will only be used for precursor process gases whose relative density is greater than that of ambient air.

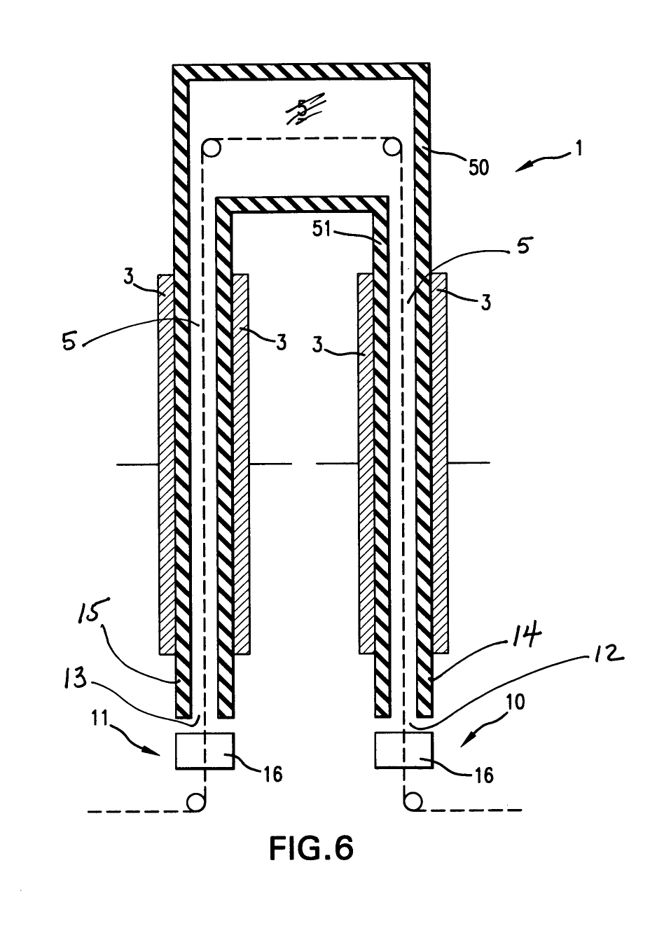

Referring now to FIG. 6, there is illustrated a still further construction of APP system, again identified by the numeral 1. The electrodes 3 are mounted on a pair of U-shaped dielectric members of dielectric material, namely, an outer U-shaped dielectric member 50 and an inner U-shaped member 51. It will be noted that the inner U-shaped member 51 nests within the outer U-shaped member 50 to form the plasma region, again identified by the reference numeral 5 therebetween. The outer U-shaped member carries electrodes 3 and the inner surface of the inner U-shaped member 51 carries the other electrode 3. It will be appreciated that the outer electrode member 50 is an enclosed member, in other words, the ends of the U-shape are closed off to form the outer portion of an enclosure housing, as in this embodiment.

Referring now to FIGS. 7 to 12 inclusive, there is illustrated portion of an APP system used for the handling of continuous fibre or yarn, hereinafter “yarn”, in a system. The system comprises a multipass fibre handling system. In FIG. 7, there is illustrated this construction of APP system, again indicated generally by the reference numeral 1. In this APP system, there is provided an enclosure housing formed from electrode boxes 63 mounted on a system support frame 60 housed within a further frame 61 covered by metal mesh panels 62 forming a Faraday cage. The metal mesh panels 62 are grounded to complete the Faraday cage.

Referring now to FIG. 9, there is illustrated a pair of electrode containing boxes 63 forming part of the enclosure housing. A sealing strip 64 seals the sides of both electrode boxes together and a gas containment lid 65 completes another wall of the enclosure housing. The gas containment lid 65 includes a gas inlet pipe 66. A yarn support rack, indicated generally by the reference numeral 70, comprising an open frame 71 mounting opposed pulleys 72 is provided. The yarn support rack 70 includes a base 73 forming effectively the enclosure housing base and has a hole forming a yarn entry port assembly 75 and a hole forming a yarn exit port 76. The outer portion of the each electrode box 63 is of dielectric material and will house an electrode, again identified by the reference numeral 3, as can be seen in FIG. 10.

It will be appreciated that yarn can be fed back and forth across the pulleys providing increased path length and resident time within the plasma region.

It will be appreciated that the present invention has certain advantages over the prior art in that the high cost involved in using large quantities of expensive gases is largely eliminated. Further, health and safety may be improved, together with a reduction in atmospheric pollution. The present invention provides a more efficient system in that problems of repeatability due to contamination from other gases in the plasma region, are greatly reduced. Anything that can be done to reduce the dragging of gas in or out of the enclosure housing 2 will be advantageous. Thus, as mentioned already, lip seals, brush seals, opposing rollers, security curtains and the like may be used.

It will be appreciated that the electrode geometry is not limited to opposing parallel plate geometry but may comprise practically any geometry, including 3-dimensional non-planar electrodes, for example, point, namely needle array electrodes, wire electrodes, cylindrical electrodes, and so on. It is envisaged that such a configuration used for helium gas provides a surface activation process which can be applied to many materials including, plastics, polymers, inorganics and metal.

In one embodiment, helium as a precursor process gas, can be provided with a radio frequency supply of between 50 to 80 kHz, powered by a suitable RF transformer generating about 2 to 6 Kv and using about 1 kW of power. This successfully activates polyolefin textile web, as measured by wettabilty and adhesion after bonding. It was found that when this was run in accordance with the present invention, less than 5% of the quantity of helium gas required in the absence of the gas containment according to the present invention was required. Similarly, argon gas can be used in substantially much the same power and radio frequency ratio.

Various other systems according to the present invention have been used in which precursor process gas contained a mixture comprising argon, together with a fluorine containing halocarbon gas such as C₂F₆, CF₄ or CHF₃. It has been used to deposit a conformal fluorocarbon coating onto any web or work-piece passing through the plasma. Similarly, a gas mixture comprising argon and siloxane vapour deposits a conformal coating of SiOₓ onto any web or work-piece passing through the plasma. A system powered with about 5 to 100 Hz AC current and used with argon gas mobilises fine powder placed in the plasma region and impregnates porous material situated in the same region with such powder.

It is envisaged that the present invention is particularly directed to plasma activation and coating and thin film deposition and also to any surface contamination cleaning and etching.

In the specification the terms “comprise, comprises, comprised and comprising” or any variation thereof and the terms “include, includes, included and including” or any variation thereof are considered to be totally interchangeable and they should all be afforded the widest possible interpretation.

The invention is not limited to the embodiments hereinbefore described but may be varied in both construction and detail within the scope of the claims.

1. An atmospheric pressure plasma (APP) system (1) of the non-thermal equilibrium type comprising: electrodes (3) forming a plasma region mounted in an enclosure housing (2) a non-ambient air precursor process gas having a relative density greater or less than ambient air at the same pressure and temperature, characterised in that the system comprises: a gas-tight enclosure housing (2) having an open to the atmosphere entry port assembly (10) and exit port assembly (11), each assembly port having a work-piece port opening (12, 13) and a work-piece enclosure opening (14, 15), wherein the port assemblies are above the plasma region (5) for precursor process gas with a relative density greater than that of the ambient air and below for a gas with a relative density less than that of ambient air, and means (20) for moving work-pieces between the electrodes (3) from the entrance port assembly (10) to the exit port assembly (11).

2. An atmospheric pressure plasma (APP) system (1) as claimed in claim 1 in which each port assembly (10, 11) comprises an elongate enclosed housing with the work-piece port opening (12, 13) and the work-piece enclosure opening spaced (14, 15) vertically apart.

3. An atmospheric pressure plasma (APP) system (1) as claimed in claim 1 or 2 in which the gas analyser (30) is mounted in the entry port assembly (10).

4. An atmospheric pressure plasma (APP) system (1) as claimed in any preceding claim in which a gas analyser (30) is located adjacent the work-piece enclosure opening (14, 15).

5. An atmospheric pressure plasma (APP) system (1) as claimed in any preceding claim in which a gas analyser (30) is mounted in the exit port (11).

6. An atmospheric pressure plasma (APP) system (1) as claimed in any preceding claim in a gas analyser (30) is mounted adjacent the work-piece port opening (10).

7. An atmospheric pressure plasma (APP) system (1) as claimed in any of claims 3 to 6 in which the gas analyser (30) is connected to a control means (37) for the introduction of precursor process gas on the quantity of precursor process gas sensed by the analyser (30) falling below a predetermined level.

8. An atmospheric pressure plasma (APP) system (1) as claimed in any preceding claim in which the precursor process gas is maintained at a positive pressure above ambient pressure outside the enclosure housing (2).

9. An atmospheric pressure plasma (APP) system (1) as claimed in claim 8 in which the positive pressure of the precursor process gas is less than 10% of ambient.

10. An atmospheric pressure plasma (APP) system (1) as claimed in claim 9 in which the positive pressure of the precursor process gas is of the order of 1% of ambient.

11. An atmospheric pressure plasma (APP) system (1) as claimed in any of claims 8 to 10 in which control means (37) are provided whereby the positive pressure is maintained by the introduction of precursor process gas when the pressure within the enclosure housing (2) falls below a predetermined minimum level.

12. An atmospheric pressure plasma (APP) system (1) as claimed in any preceding claim in which means (25) are provided for continuously introducing precursor process gas into the enclosure housing (2).

13. An atmospheric pressure plasma (APP) system (1) as claimed in any preceding claim in which means (43) are provided for the collection and removal of gases adjacent the exterior of each port assembly (10, 11) where a work-piece enters or leaves the port assembly (10, 11).

14. An atmospheric pressure plasma (APP) system (1) as claimed in claim 13 in which the means for collection and removal of the gases comprise a cowling (44) surrounding the port assemblies (10, 11) and an extraction fan (46) associated therewith.

15. An atmospheric pressure plasma (APP) system (1) as claimed in claim 14 in which the cowling (44) comprises an open gas receiving mouth adjacent the work-piece port opening (12).

16. An atmospheric pressure plasma (APP) system (1) as claimed in any preceding claim in which an exhaust gas vent is provided in the enclosure on the side of the enclosure opposite to the port assemblies (10, 11) for the collection of exhaust gases having a relative density to that of the process precursor gases whereby they are trapped in the enclosure housing (2).

17. An atmospheric pressure plasma (APP) system (1) as claimed in claim 16 in which an exhaust gas sensor (40) is mounted in the enclosure housing (2) adjacent the exhaust gas vent.

18. An atmospheric pressure plasma (APP) system (1) as claimed in claim 17 in which control means (42) are connected to the exhaust gas sensor (40) and the exhaust gas vent for the operation of the exhaust gas vent on the level of exhaust gases in the enclosure housing (2) exceeding a predetermined level.

19. An atmospheric pressure plasma (APP) system (1) as claimed in any preceding claim in which gas flow dampers (16) are mounted in each port assembly.

20. An atmospheric pressure plasma (APP) system (1) as claimed in claim 19 in which the gas flow dampers (16) comprise one or more of:
lip seals;
brush seals;
curtain seals; and
opposed rollers.

21. An atmospheric pressure plasma (APP) system (1) as claimed in any preceding claim in which the electrodes (3) are substantially planar electrodes.

22. An atmospheric pressure plasma (APP) system (1) as claimed in claim 21 in which there are a plurality of electrodes (3) arranged back to back and in which the means for moving the work-pieces between the electrodes comprises a conveyor (20) or a web moving back and forth sequentially between the electrodes (3).

23. An atmospheric pressure plasma (APP) system (1) as claimed in claim 21 in which the work-piece is endless yarn and the means for moving the work-piece comprises an open frame member (71) for mounting between two electrodes (3), the frame member carrying a plurality of yarn support pulleys (72) on opposite sides of the frame member (71) and a yarn draw-off mechanism.

24. An atmospheric pressure plasma (APP) system (1) as claimed in any of claims 21 to 23 in which the electrodes (3) comprise a pair of U-shaped members (50, 51) of dielectric material nesting one inside the other to define the plasma region (5) therebetween carrying an electrode (3) on the outer surface of the outer of the two members (50) and carrying a corresponding electrode on the inner surface of the other member (51).

25. An atmospheric process plasma (APP) system (1) of the non thermal equilibrium type comprising: electrodes (3) forming a plasma region mounted in a gas-tight enclosure housing (2) having an open to the atmosphere entry port assembly (10) and exit port assembly (11), a non-ambient air precursor process gas having a relative density greater or less than ambient air at the same pressure and temperature and means (20) for moving work-pieces between the electrodes (3) for the entrance port assembly (10) to the exit port assembly (11) characterized in that each assembly port (10. 11) comprises an elongate enclosed housing having a work-piece port opening (12, 13) connecting the housing to the outside of the enclosure housing (2) and a vertically spaced-apart work-piece enclosure opening (14, 15) connecting the housing to the enclosure housing (2) and wherein the work-piece enclosure opening (14, 15) is below the work-piece port opening (12, 13) and is sited in the enclosure housing (2) above the plasma region (5) for precursor process gas with a relative density greater than that of the ambient air and below the plasma region (5) and above the work-piece enclosure opening (14, 15) for a gas with a relative density less than that of ambient air.

26. An atmospheric process plasma (APP) system (1) as claimed in claim 25 which the gas analyzer (30) is mounted in the entry port assembly (10).

7. An atmospheric process plasma (APP) system (1) as claimed in claim 25 in which a gas analyzer (30) is located adjacent the work-piece enclosure opening (14, 15).

28. An atmospheric process plasma (APP) system (1) as claimed in claim 25 in which a gas analyzer (30) is mounted in the exit port (11).

29. An atmospheric process plasma (APP) system (1) as claimed in claim 25 in which a gas analyzer (30) is mounted adjacent the work-piece port opening (10).

30. An atmospheric process plasma (APP) system (1) as claimed in claim 26 in which the gas analyzer (30) is connected to a control means (37) for the introduction of precursor process gas on the quantity of precursor process gas sensed by the analyzer (30) falling below a predetermined level.

31. An atmospheric process plasma (APP) system (1) as claimed in claim 25 in which the precursor process gas is maintained at a positive pressure above ambient pressure outside the enclosure housing (2).

32. An atmospheric process plasma (APP) system (1) as claimed in claim 31 in which the positive pressure of the precursor process gas is less than 10% of ambient.

33. An atmospheric process plasma (APP) system (1) as claimed in claim 32 in which the positive pressure of the precursor process gas is of the order of 1% of ambient.

34. An atmospheric process plasma (APP) system (1) as claimed in claim 31 in which control means (37) are provided whereby the positive pressure is maintained by the introduction of precursor process gas when the pressure within the enclosure housing (2) falls below a predetermined minimum level.

35. An atmospheric process plasma (APP) system (1) as claimed in claim 25 in which means (25) are provided for continuously introducing precursor process gas into the enclosure housing (2).

36. An atmospheric process plasma (APP) system (1) as claimed in claim 25 in which means (43) are provided for the collection and removal of gases adjacent the exterior of each port assembly (10, 11) where a work-piece enters or leaves the port assembly (10,11).

37. An atmospheric process plasma (APP) system (1) as claimed in claim 36 in which the means for collection and removal of the gases comprise a cowling (44) surrounding the port assemblies and an extraction fan (46) associated therewith.

38. An atmospheric process plasma (APP) system (1) as claimed in claim 37 in which the cowling (44) comprises an open gas receiving mouth adjacent the work-piece port opening (12).

39. An atmospheric process plasma (APP) system (1) as claimed in claim 25 in which an exhaust gas vent is provided in the enclosure on the side of the enclosure opposite to the port assemblies (10. 11) for the collection of exhaust gases having a relative density to that of the process precursor gases whereby they are trapped in the enclosure housing (2).

40. An atmospheric process plasma (APP) system (1) as claimed in claim 39 in which an exhaust gas sensor (40) is mounted in the enclosure housing (2) adjacent the exhaust gas vent.

41. An atmospheric process plasma (APP) system (1) as claimed in claim 40 in which control means (42) are connected to the exhaust gas sensor (40) and the exhaust gas vent for the operation of the exhaust gas vent on the level of exhaust gases in the enclosure housing (2) exceeding a predetermined level.

42. An atmospheric process plasma (APP) system (1) as claimed in claim 25 in which gas flow dampers (16) are mounted in each port assembly.

43. An atmospheric process plasma (APP) system (1) as claimed in claim 42 in which the gas flow dampers comprise one or more of:
lip seals;
brush seals;
curtain seals; and
opposed rollers.

44. An atmospheric process plasma (APP) system (1) as claimed in claim 25 in which the electrodes (3) are substantially planar electrodes.

45. An atmospheric process plasma (APP) system (1) as claimed in claim 44 in which there are a plurality of electrodes (3) arranged back to back and in which the means for moving the work-pieces between the electrodes comprises a conveyor (20) moving back and forth sequentially between the electrodes (3).

46. An atmospheric process plasma (APP) system (1) as claimed in claim 20 in which the work-piece is endless yarn and the means for moving the work-piece comprises an open frame member (71) for mounting between two electrodes (3), the frame member carrying a plurality of yarn support pulleys (72) on opposite sides of the frame member (71) and a yarn draw-off mechanism.

47. An atmospheric process plasma (APP) system (1) as claimed in claim 25 in which the electrodes (3) comprise a pair of U-shaped members (50, 51) of dielectric material nesting one inside the other to define the plasma region (5) therebetween carrying an electrode (3) on the outer surface of the outer of the two members (50) and carrying a corresponding electrode on the inner surface of the other member (51).
